(19) United States
(12) Patent Application Publication
(10) Pub. No.: US 2021/0280389 A1
(43) Pub. Date: Sep. 9, 2021

(54) LARGE-AREA VHF PECVD CHAMBER FOR LOW-DAMAGE AND HIGH-THROUGHPUT PLASMA PROCESSING

(71) Applicant: Applied Materials, Inc., San Clara, CA (US)

(72) Inventors: Shuran SHENG, Saratoga, CA (US); Shinobu ABE, Osaka (JP); Keita KUWAHARA, Osaka (JP); Su Ho CHO, Santa Clara, CA (US)

(73) Assignee: Applied Materials, Inc., Santa Clara, CA (US)

(21) Appl. No.: 16/321,660

(22) PCT Filed: Jul. 31, 2017
(86) PCT No.: PCT/US2017/044750

§ 371 Date: Jan. 29, 2019

(51) Int. Cl. H01J 37/32; C23C 16/458; C23C 16/505

(52) U.S. Cl. CPC H01J 37/32174; C23C 16/4586; C23C 16/505; H01J 37/3244; H01J 37/32807; H01J 37/32577; C23C 16/4581

(57) ABSTRACT

Embodiments disclosed herein generally relate to a plasma processing system for modifying the uniformity pattern of a thin film deposited in a plasma processing chamber which includes at least one VHF power generator coupled to a diffuser within the plasma processing chamber. The feeding location offset of each VHF power generator and the controlling of each VHF power generator via phase modulation and sweeping allows for plasma uniformity improvements by compensating for the non-uniformity of the thin film patterns produced by the chamber, due to the standing wave effect. The power distribution between the multiple VHF power generators coupled to and/or disposed at different locations on the backing plate may be produced by dynamic phase modulation between the VHF power applied at the different coupling points.

### BACKGROUND

### Field of the Disclosure

Embodiments of the present disclosure generally relate to a system and apparatus for substrate processing. More specifically, embodiments of the present disclosure relate to processing in a plasma processing chamber having a diffuser and one or more VHF power generators and/or feeds for improved plasma uniformity by compensating for the plasma standing wave effect and improved flow pattern modulation by providing pinhole scooping.

### Description of the Related Art

Plasma processing, such as plasma-enhanced chemical vapor deposition (PECVD), is generally employed to deposit thin films on substrates, such as semiconductor substrates, flat panel substrates, solar panel substrates, and liquid crystal display substrates. PECVD is generally accomplished by introducing a precursor gas into a vacuum chamber having a substrate disposed on a substrate support. The precursor gas is typically directed through a gas distribution plate situated near the top of the vacuum chamber. The precursor gas in the vacuum chamber is energized (e.g. excited) into a plasma by applying radio frequency (RF) power to the chamber from one or more RF sources coupled to the chamber. The excited gas reacts to form a layer of material on a surface of the substrate that is positioned on a temperature controlled substrate support. The distribution plate is generally connected to a RF power source, for example a VHF power generator, and the substrate support is typically connected to the chamber body providing a RF current return path.

Uniformity of such thin films, both in thickness and quality, is generally desired in the thin films deposited using PECVD processes. As the demand for larger LCDs and solar panels continues to grow, so does the size of the substrate that is used to make the LCDs and solar panels. As the substrates continue to increase in size, it is increasingly difficult to attain such uniformity. Furthermore, the requirement for thickness uniformity and other film properties often become even more stringent.

In addition, during large-area VHF PECVD processing, the electromagnetic field above the substrate is not uniform due to the standing wave effect, thus resulting in a plasma formed having a plasma sheath that bends towards the substrate proximate the edge of the substrate. Such bending of the plasma sheath leads to differences in the ion trajectories bombarding the substrate proximate the edge of the substrate as compared to the center of the substrate, thereby causing a non-uniform processing of the substrate and thus affecting overall critical dimension uniformity.

Furthermore, asymmetries inherent in the configuration of many chemical vapor deposition reactors can further compound difficulties in achieving thin film uniformity. For example, connection of the radio-frequency power feed at the center point of a PECVD chamber discharge electrode, while conductive to producing a radially uniform electric field, can be inaccessible due to the presence of other external chamber components that prevent the connection at the center point of the electrode. Thus, a radio-frequency power feed for some PECVD chambers maybe positioned on the discharge electrode at some point besides the geometric center, which is generally suboptimal with respect to generating a radially symmetric electric field in the chamber. Non-symmetric electric fields will generally cause a plasma generated in the processing region of a processing chamber to be non-uniform, which will cause the deposition or etching process performed in the processing chamber to be non-uniform.

Accordingly, there is a need in the art for apparatus and system that facilitates improved uniformity of a deposition process performed in a plasma processing chamber. Specifically, there is a need in the art for an improved VHF power generation configuration and match network tuning scheme for compensating for the standing wave effect and plasma asymmetric distribution, as well as to improve uniformity.

### SUMMARY

Embodiments disclosed herein generally relate to a plasma processing system for modifying the uniformity pattern of a thin film deposited in a plasma processing chamber which includes at least one radio-frequency (RF) power generator coupled to a diffuser within the plasma processing chamber. In one embodiment, a plasma processing chamber is disclosed. The plasma processing chamber includes a diffuser, a backing plate, and a VHF power generator. The backing plate is coupled to the diffuser. The backing plate has a first corner location, a second corner location, a third corner location, and a fourth corner location. Furthermore, the backing plate has an opening at a substantial center of the backing plate for a gas feed. The VHF power generator is coupled to the backing plate at the first corner location, the second corner location, the third corner location, and the fourth corner location.

In another embodiment, a plasma processing chamber is disclosed. The plasma processing chamber includes a diffuser, a backing plate, a first VHF power generator, a second VHF power generator, a third VHF power generator, a fourth VHF power generator, and a controller. The backing plate is coupled to the diffuser, and has an opening at a substantial center of the backing plate for a gas feed. The first VHF power generator is coupled to the backing plate at a first radius from a center of the backing plate and at a first azimuth angle. The second VHF power generator is coupled to the backing plate at a second radius from the center of the backing plate and at a second azimuth angle. The third VHF power generator is coupled to the backing plate at a third radius from the center of the backing plate and at a third azimuth angle. The fourth VHF power generator coupled to the backing plate at a fourth radius from the center of the backing plate and at a fourth azimuth angle. The controller is operatively connected to the plasma processing chamber. Furthermore, the controller is programmed to control operation of the first VHF power generator, the second VHF power generator, the third VHF power generator, and the fourth VHF power generator.

In another embodiment, a plasma processing chamber is disclosed. The plasma processing chamber includes a diffuser, a backing plate, a plurality of VHF power generators, and at least one magnetic ferrite block. The backing plate is coupled to the diffuser. Furthermore, the backing plate has an opening at a substantial center of the backing plate for a gas feed. Each VHF power generator is coupled to the backing plate at a location disposed approximate an edge of the backing plate. The at least one magnetic ferrite block is coupled to the backing plate.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic cross-sectional view of an illustrative plasma processing system having one embodiment of a gas distribution plate assembly, according to one embodiment disclosed herein.

FIG. 2A is a schematic perspective view of a plasma processing chamber having one VHF power generator disposed therein, according to one embodiment disclosed herein.

FIG. 2B is a schematic perspective view of a plasma processing chamber having more than one VHF power generator disposed therein, according to one embodiment disclosed herein.

FIG. 2C is a schematic perspective view of a plasma processing chamber having a plurality of VHF power generators disposed therein, according to one embodiment disclosed herein.

FIG. 3A is a schematic cross-sectional view of a diffuser plate, according to one embodiment disclosed herein.

FIG. 3B is a schematic cross-sectional view of a diffuser plate, according to one embodiment disclosed herein.

FIG. 4 is an isometric view of a compressible spring member, according to one embodiment disclosed herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments disclosed herein generally relate to a plasma processing system for modifying the uniformity pattern of a thin film deposited in a plasma processing chamber which includes at least one VHF power generator coupled to a diffuser within the plasma processing chamber. The feeding location offset of each VHF power generator and the controlling of each VHF power generator via phase modulation and sweeping allows for plasma uniformity improvements by compensating for the non-uniformity of the thin film patterns produced by the chamber, due to the standing wave effect. The power distribution between the multiple VHF power generators coupled to and/or disposed at different locations on the backing plate may be produced by dynamic phase modulation between the VHF power applied at the different coupling points. Embodiments of the present disclosure are generally utilized in processing rectangular substrates, such as substrates for liquid crystal displays or flat panels, and substrate for solar panels. Other suitable substrates may be circular, such as semiconductor substrates. The chambers used for processing substrates typically include a substrate transfer port formed in a sidewall of the chamber for transfer of the substrate. The transfer port generally includes a length that is slightly greater than one or more major dimensions of the substrate. The transfer port may produce challenges in RF return schemes. The present disclosure may be utilized for processing substrates of any size or shape. Suitable chambers that may be used to implement the disclosure are available from AKT America, a subsidiary of Applied Materials, Inc., located in Santa Clara, Calif.

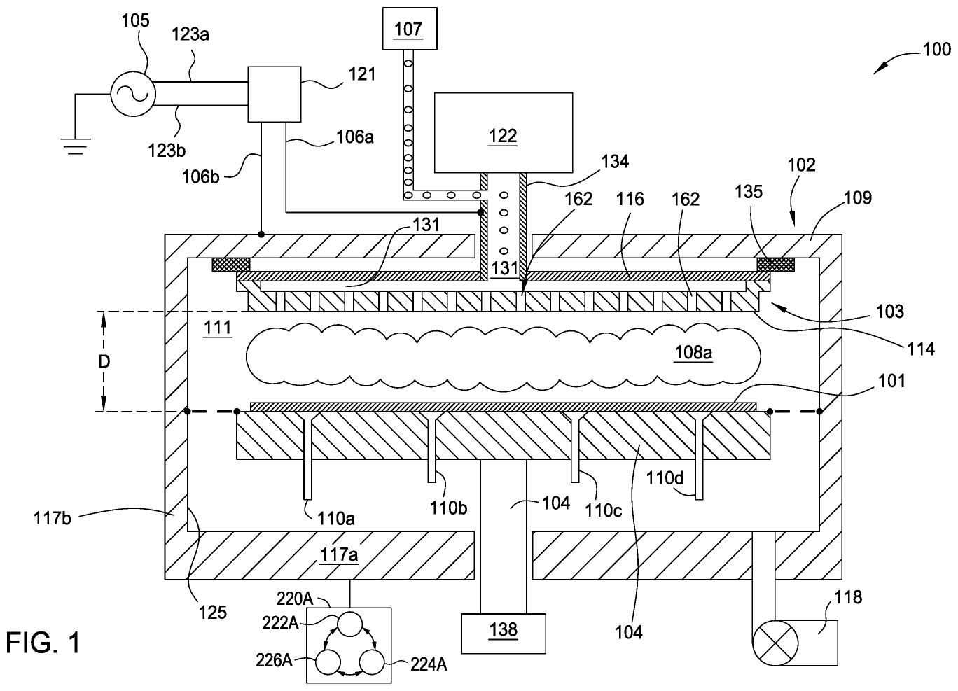

FIG. 1 is a schematic cross-sectional view of one embodiment of a plasma processing system 100. The plasma processing system 100 is configured to process a large area substrate 101 using plasma in forming structures and devices on the large area substrate 101 for use in the fabrication of liquid crystal displays (LCDs), flat panel displays, organic light emitting diodes (OLEDs), or photovoltaic cells for solar cell arrays. The substrate 101 may be a thin sheet of metal, plastic, organic material, silicon, glass, quartz, or polymer, among other suitable materials. The structures may be thin film transistors which may comprise a plurality of sequential deposition and masking steps. Other structures may include p+aSi/n−cSi p-n heterojunctions to form diodes for photovoltaic cells. The plasma processing system 100 may be configured to deposit a variety of materials on the substrate 101, including, but not limited to, dielectric materials or amorphous silicon.

As shown in FIG. 1, the plasma processing system 100 generally comprises a chamber body 102 including a bottom 117a and sidewalls 117b that at least partially defines a processing volume 111. The sidewalls 117b support a lid assembly 109. The lid assembly 109 provides an upper boundary to the processing volume 111. A substrate support 104 is disposed in the processing volume 111. The substrate support 104 is adapted to support the substrate 101 on a top surface during processing. The substrate support 104 is coupled to an actuator 138 adapted to move the substrate support at least vertically to facilitate transfer of the substrate 101 and/or adjust a distance D between the substrate 101 and a diffuser plate 103. One or more lift pins 110a, 110b, 110c and 110d may extend through the substrate support 104. The lift pins 110a-110d are adapted to contact the bottom 117a of the chamber body 102 and support the substrate 101 when the substrate support 104 is lowered by the actuator 138 in order to facilitate transfer of the substrate 101. In a processing position, as shown in FIG. 1, the lift pins 110a-110d are adapted to be flush with or slightly below the upper surface of the substrate support 104 to allow the substrate 101 to lie flat on the substrate support 104.

The diffuser plate 103 is configured to supply a processing gas to the processing volume 111 from a processing gas source 122. The plasma processing system 100 also comprises an exhaust system 118 configured to apply negative pressure to the processing volume 111. The diffuser plate 103 is generally disposed opposing the substrate support 104 in a substantially parallel relationship.

In one embodiment, the diffuser plate 103 comprises a gas distribution plate 114 and a backing plate 116. The backing plate 116 may function as a blocker plate to enable formation of a gas volume 131 between the gas distribution plate 114 and the backing plate 116. The gas source 122 is connected to the gas distribution plate 114 by a conduit 134. In one embodiment, a remote plasma source 107 is coupled to the conduit 134 for supplying a plasma of activated gas through the gas distribution plate 114 to the processing volume 111. The plasma from the remote plasma source 107 may include activated gases for cleaning chamber components disposed in the processing volume 111. In one embodiment, activated cleaning gases are flowed to the processing volume 111.

The gas distribution plate 114, the backing plate 116, and the conduit 134 are generally formed from electrically conductive materials and are in electrical communication with one another. The chamber body 102 is also formed from an electrically conductive material. The chamber body 102 is generally electrically insulated from the diffuser plate 103. In one embodiment, the diffuser plate 103 is mounted on the chamber body 102 by an insulator 135.

In one embodiment, the substrate support 104 is also electrically conductive, and the substrate support 104 and the diffuser plate 103 are configured to be opposing electrodes for generating a plasma 108a of processing gases therebetween during processing and/or a pre-treatment or post-treatment process. In one embodiment, a plurality of gas passages 162 are formed through the diffuser plate 103 to allow a predetermined distribution of gas passing through the gas distribution plate 114 and into the process volume 111.

A VHF power generator 105 is generally used to generate the plasma 108a between the diffuser plate 103 and the substrate support 104 before, during and after processing, and may also be used to maintain energized species or further excite cleaning gases supplied from the remote plasma source 107. In one embodiment, the VHF power generator 105 is coupled to the diffuser plate 103 by a first line 106a of an impedance matching circuit 121. A second line 106b of the impedance matching circuit 121 is electrically connected to the chamber body 102.

During processing, one or more processing gases are flowed to the processing volume 111 from the gas source 122 through the diffuser plate 103. A RF power is applied between the diffuser plate 103 and the substrate support 104 to generate a plasma 108a from the processing gases for processing the substrate 101. Uniformity of plasma distribution is generally desired during processing, although tuning of the plasma uniformity may also be useful. However, the distribution of the plasma 108a is determined by a variety of factors, such as distribution of the processing gas, geometry of the processing volume 111, the distance D between the diffuser plate 103 and the substrate support 104, variations between deposition processes on the same substrate or different substrates, and deposition processes and cleaning process. The spacing between, or distance D, between the substrate support 104 and the showerhead assembly may be adjusted during pre-treatment, post-treatment, processing and cleaning in order to vary the ground return RF return paths.

In FIG. 1, the RF current path may be indicative of RF current flow during processing of the substrate 101. The RF current generally travels from a first lead 123a of the VHF power generator 105 to the first line 106a of the impedance matching circuit 121, then travels along an outer surface of the conduit 134 to a back surface of the backing plate 116, then to a front surface of the gas distribution plate 114. From the front surface of the gas distribution plate 114, the RF current goes through plasma 108a and reaches a top surface of the substrate 101 or the substrate support 104 to an inner surface 125 of the chamber body 102. From the inner surface 125, the RF current returns to a second lead 123b of the VHF power generator 105 from the impedance matching circuit 121.

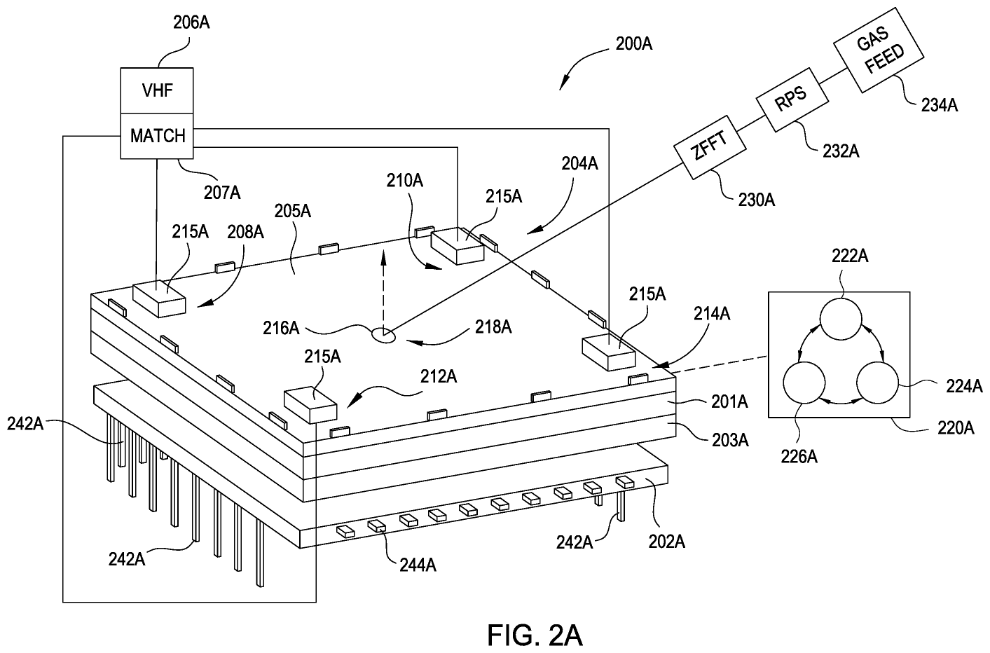

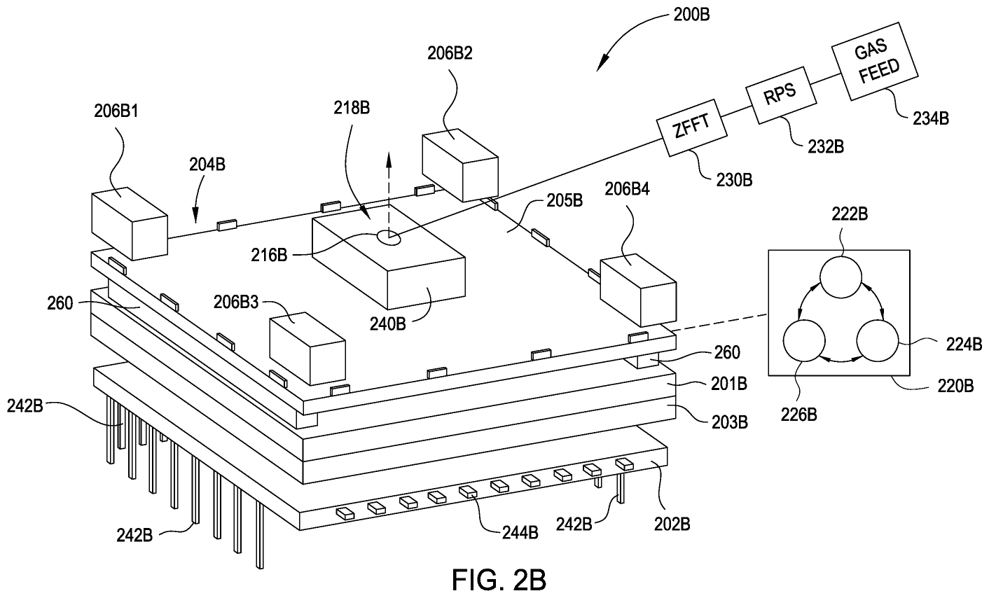

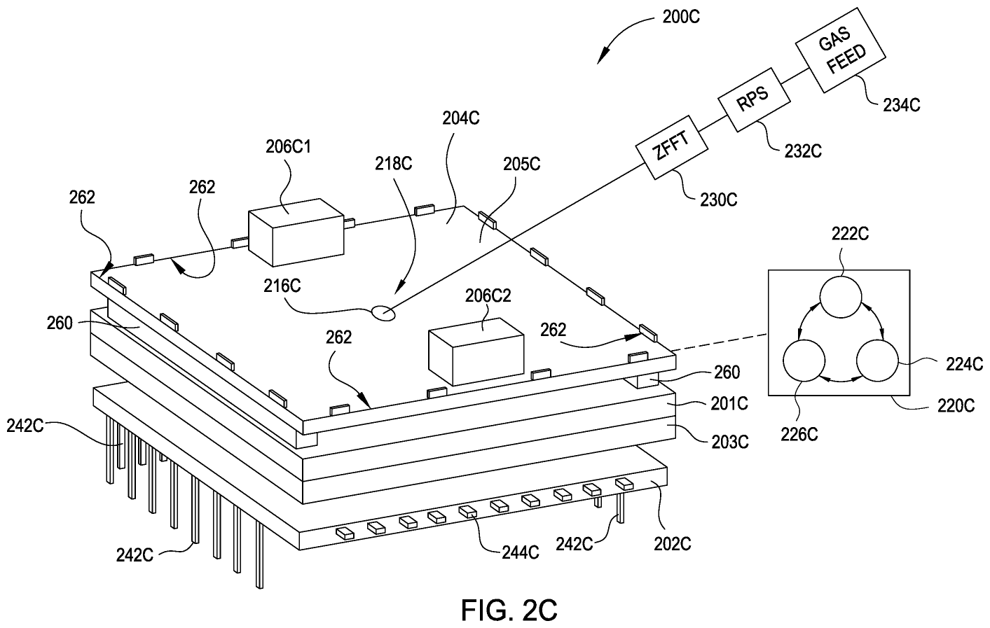

FIG. 2A is a schematic perspective view of plasma processing chamber components 200A for a plasma enhanced chemical vapor deposition system, according to one embodiment. The plasma processing chamber components 200A includes a susceptor 202A and chamber lid assembly 204A. The susceptor 202A may be utilized in the plasma enhanced chemical vapor deposition system 100, as shown in FIG. 1, such as within and/or coupled to the chamber body 102 of the plasma processing system 100, in lieu of substrate support 104. It is contemplated, however, that the disclosed susceptor 202A and chamber lid assembly 204A may be utilized in and/or with any suitable plasma processing chamber. As shown, the susceptor 202A includes ground straps 242A and ground contacts 244A and is disposed opposite the chamber lid assembly 204A. In some embodiments, the chamber lid assembly 204A includes the backing plate 201A, the diffuser plate 203A, and cover plate 205A. In other embodiments, a skirt (not shown) may be disposed between the diffuser plate 203A and the backing plate 201A. The susceptor 202A and/or the chamber lid assembly 204A assist with the modifying of the uniformity pattern of a thin film deposited in the plasma processing chamber which includes as least one radio frequency (RF) power source. In some embodiments, the RF power source may be a VHF power generator, such as the VHF power generator 206A shown in FIG. 2A. In some embodiments, the VHF power generator 206A is coupled to an RF match 207A. In some embodiments, RF match 207A is an automatic match. In some embodiments, the VHF power generator 206A and RF match 207A are mounted to a lid of the chamber body 102 of the plasma processing system 100, such as, for example, lid assembly 109 shown in FIG. 1 or to cover plate 205A shown in FIG. 2A. The backing plate 201A may have a shape similar to a shape of the diffuser plate 203A and both the backing plate 201A and the diffuser plate 203A may have a shape similar to susceptor 202A and/or a shape with at least four distinct sides. It is contemplated, however, that the cover plate 205A, the diffuser plate 203A, backing plate 201A and/or the susceptor 202A may have any suitable shape and/or any suitable number of sides. The susceptor 202A and/or chamber lid assembly 204A assist with the modifying of the uniformity pattern of a thin film deposited in a plasma processing chamber which includes at least one VHF power generator 206A electrically coupled to the backing plate 201A and diffuser plate 203A within the plasma processing chamber.

As shown in FIG. 2A, the cover plate 205A has a first corner location 208A, a second corner location 210A, a third corner location 212A, and a fourth corner location 214A where each corner location aligns with the corner locations of the backing plate 201A and the diffuser plate 203A. The cover plate 205A also has an opening 216A at a substantial center 218A of the cover plate 205A. In some embodiments, a gas feed 234A may be disposed through the opening 216A. As such, the opening 216A is configured to hold and/or support the gas feed 234A.

The VHF power generator 206A is electrically coupled to the diffuser plate 203A at at least one location via backing plate 201A. In some embodiments, the VHF power generator 206A may be electrically coupled to the diffuser plate 203A at more than one location via backing plate 201A. As shown, the VHF power generator 206A is coupled to each of the corner locations of the diffuser plate 203A via backing plate 201A via corner locations on cover plate 205A at the first corner location 208A, the second corner location 210A, the third corner location 212A, and the fourth corner location 214A. In some embodiments, the VHF power generator 206A and the main RF match 207A are coupled to fixed matches 215A located at each of the first corner location 208A, the second corner location 210A, the third corner location 212A and the fourth corner location 214A. In some embodiments, the main RF match 207A is an automatic match. In some embodiments, each connection location of the VHF power generator 206A and the main RF match 207A to the cover plate 205A may be disposed equidistant from the center 218A of the cover plate 205A. The VHF power generator 206A and the main RF match 207A are electrically connected to the backing plate 201A via the fixed RF matches 215A mounted at each corner location of cover plate 205A via suitable electrical connectors between the fixed matches 215A and the backing plate 201A through openings (not shown) in the cover plate below each fixed RF match 215A.

In some embodiments, the plasma processing chamber 200A may be operatively connected to a zero field feed through (ZFFT) 230A. The ZFFT 230A may minimize parasitic plasma. A parasitic plasma may be generated in the gas feed lines due to the existence of a high electrical field within the gas feed lines. The ZFFT 230A helps eliminate the parasitic plasma within the gas feed lines which reduces the particle formation upstream of the diffuser plate 203A. Furthermore, the ZFFT 230A may be operatively connected to a remote plasma source (RPS) 232A. The RPS 232A may be operatively connected to the gas feed 234A.

Referring to both FIG. 1 and FIG. 2A, a controller 220A is operatively connected to the chamber body 102 of the plasma processing system 100 and/or the VHF power generator 206A. The controller 220A is programmed to control operation of the VHF power generator 206A. In some embodiments, the controller 220A is programmed to control operation of the VHF power generator 206A at the first corner location 208A, the second corner location 210A, the third corner location 212A, and/or the fourth corner location 214A. In some embodiments, the controller 220A is programmed to control operation of the VHF power generator 206A at the first corner location 208A, the second corner location 210A, the third corner location 212A, and/or the fourth corner location 214A at a first frequency via the main RF match 207A. In some embodiments, the controller 220A is programmed to control operation of the VHF power generator 206A via the main RF match 207A and via fixed matches 215A positioned at each one of first corner location 208A, the second corner location 210A, third corner location 212A, and at the fourth corner location 214A at a first frequency. In some embodiments, the first frequency may be between about 20 MHz and about 100 MHz, for example, between about 30 MHz and about 70 MHz, such as about 60 MHz. Furthermore, the controller 220A is programmed to provide quasi-static phase control between the main RF match 207A and the fixed matches 215A located at each corner location 208A, 210A, 212A and 214A. In some embodiments, phase-shifters are provided between the main RF match 207A and the fixed matches 215A, and the controller 220A is programmed to perform dynamic phase modulation and sweeping.

The above-described chamber body 102 of the plasma processing system 100 can be controlled by a processor based system controller, such as controller 220A. The controller 220A includes a programmable central processing unit (CPU) 222A that is operable with a memory 224A and a mass storage device, an input control unit, and a display unit (not shown), such as power supplies, clocks, cache, input/output (I/O) circuits, and the like, coupled to the various components of the chamber body 102 of the plasma processing system 100 to facilitate control of the substrate processing. The controller 220A also includes hardware for monitoring substrate processing through sensors (not shown) in the chamber body 102 of the plasma processing system 100.

To facilitate control of the chamber body 102 of the plasma processing system 100 described above, the CPU 222A may be one of any form of general purpose computer processor that can be used in an industrial setting, such as a programmable logic controller (PLC), for controlling various chambers and sub-processors. The memory 224A is coupled to the CPU 222A, and the memory 224A is non-transitory and may be one or more of readily available memory such as random access memory (RAM), read only memory (ROM), floppy disk drive, hard disk, or any other form of digital storage, local or remote. Support circuits 226A are coupled to the CPU 222A for supporting the processor in a conventional manner. Charged species generation, heating, and other processes are generally stored in the memory 224A, typically as a software routine. The software routine may also be stored and/or executed by a second CPU (not shown) that is remotely located from the hardware being controlled by the CPU 222A.

The memory 224A is in the form of computer-readable storage media that contains instructions, that when executed by the CPU 222A, facilitates the operation of the chamber body 102 of the plasma processing system 100. The instructions in the memory 224A are in the form of a program product such as a program that implements the method of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

FIG. 2B is a schematic perspective view of plasma processing chamber components 200B for a plasma enhanced chemical vapor deposition system, according to one embodiment. The plasma processing chamber components 200B includes a susceptor 202B and chamber lid assembly 204B. The plasma processing chamber components 200B are substantially similar to the plasma processing chamber 200A, and the susceptor 202B is substantially similar to the susceptor 202A. The susceptor 202B may be utilized in the plasma enhanced chemical vapor deposition system 100, as shown in FIG. 1, such as within and/or coupled to the chamber body 102 of the plasma processing system 100, in lieu of substrate support 104. It is contemplated, however, that the disclosed susceptor 202B and chamber lid assembly 204B may be utilized in and/or with any suitable plasma processing chamber. As shown, the susceptor 202B includes ground straps 242B and ground contacts 244B and is disposed opposite the chamber lid assembly 204B. In some embodiments, the chamber lid assembly 204B includes the backing plate 201B, the diffuser plate 203B and the cover plate 205B. In other embodiments, a skirt (not shown) may be disposed between the diffuser plate 203B and the backing plate 201B. In some embodiments, the diffuser plate 203B and the backing plate 201B are coupled to a lid of the chamber body 102 of the plasma processing system 100, such as, for example, lid assembly 109 shown in FIG. 1, or cover plate 205B shown in FIG. 2B. The backing plate 201B may have a shape similar to a shape of the diffuser plate 203B, and both the backing plate 201B and the diffuser plate 203B may have a shape similar to susceptor 202B and/or a shape with at least four distinct sides. It is contemplated, however, that the cover plate 205B, the gas diffuser plate 203A, the backing plate 201B and/or the susceptor 202B may have any suitable shape and/or any suitable number of sides.

The susceptor 202B and/or the chamber lid assembly 204B assist with the modifying of the uniformity pattern of a thin film deposited in the plasma processing chamber which includes as least one radio frequency (RF) power source disposed therein. In some embodiments, the RF power source(s) may be a VHF power generator, such as the VHF power generators 206B1, 206B2, 206B3, 206B4 discussed infra.

The plasma processing chamber 200B further includes a first VHF power generator 206B1 coupled to a first RF match, a second VHF power generator 206B2 coupled to a second RF match, a third VHF power generator 206B3 coupled to a third RF match, and a fourth VHF power generator 206B4 coupled to a fourth RF match. The first VHF power generator 206B1 and the first RF match are electrically coupled to the backing plate 201B and the diffuser plate 203B via openings (not shown) in the cover plate 205B at a first radius from the center 218B of the cover plate 205B and at a first azimuth angle. The second VHF power generator 206B2 and the second RF match are electrically coupled to the backing plate 201B and the diffuser plate 203B via openings (not shown) in the cover plate 205B at a second radius from the center 218B of the 103 via cover plate 205B and at a second azimuth angle. The third VHF power generator 206B3 and the third RF match are electrically coupled to the backing plate 201B and the diffuser plate 203B via openings in the cover plate 205B at a third radius from the center 218B of the cover plate 205B and at a third azimuth angle. The fourth VHF power generator 206B4 and the fourth RF match are electrically coupled to the backing plate 201B and the diffuser plate 203B via openings in the cover plate 205B at a fourth radius from the center 218B of the cover plate 205B and at a fourth azimuth angle. In some embodiments the RF matches are automatic RF matches. In some embodiments the RF matches are fixed matches.

Each of the second VHF power generator 206B2 and the fourth VHF power generator 206B4 are configured to generate power at a frequency between about 20 MHz and about 100 MHz, for example, between about 30 MHz and about 70 MHz, such as about 60 MHz. Furthermore, the second VHF power generator 206B2 is configured to provide power out of phase with that provided by the fourth VHF power generator 206B4, for example 180 degrees apart at the match output. By way of example only, in some embodiments, the first VHF power generator 206B1 and the third VHF power generator 206B3 may each have VHF fed therein at fixed matches at 60 MHz and 180 degrees apart at match output. Furthermore, the second VHF power generator 206B2 and the fourth VHF power generator 206B4 may each have VHF fed therein at fixed matches at 60.1 MHz and 180 degrees apart at match output. As such, a phase of 60 MHz shifts at 0.1 MHz, relative to 60.1 MHz, thus creating a phase sweeping modulation. Moreover, each of the first VHF power generator 206B1 and the third VHF power generator 206B3 are configured to generate power at the same, or similar, RF frequency, such as between about 20 MHz and about 100 MHz, for example, between about 30 MHz and about 70 MHz, such as about 40 MHz. However, the first VHF power generator 206B1 and the third VHF power generator 206B3 are each configured to generate power at a frequency that is different than a frequency of power generated by either of the second VHF power generator 206B2 and/or the fourth VHF power generator 206B4. Likewise, in certain embodiments, the second VHF power generator 206B2 and the fourth VHF power generator 206B4 are each configured to generate power at a frequency that is different than a frequency of power generated by either of the first VHF power generator 206B1 and/or the third VHF power generator 206B3. Furthermore, the first VHF power generator 206B1 is configured to provide power out of phase with that provided by the third VHF power generator 206B3, for example, 180 degrees apart. For example, the first VHF power generator 206B1 and the third VHF power generator 206B3 are each configured to generate power at a frequency of 40.68 MHz while the second VHF power generator 206B2 and the fourth VHF power generator 206B4 are each configured to generate power at a different frequency of 40.69 MHz creating phase modulation/sweeping.

As shown in FIG. 2B, the cover plate 205B has an opening 216B at a substantial center 218B of the cover plate 205B. In some embodiments, a gas feed 234B may be disposed through the opening 216B. As such, the opening 216B is configured to hold and/or support the gas feed 234B.

Furthermore, at least one magnetic ferrite block 260 is coupled to the backing plate 201B. In certain embodiments, the at least one magnetic ferrite block 260 may be disposed in a gap between the backing plate 201B and the cover plate 205B. In one embodiment, at least two magnetic ferrite blocks 260 are positioned in the gap between the diffuser plate 203B and the cover plate 205B. The magnetic ferrite blocks 260 are positioned at opposing edges and towards the side edges of the backing plate 201B. In some embodiments the magnetic ferrite blocks are positioned along edges of the backing plate 201B that have the greatest length. The magnetic ferrite blocks further assist with plasma uniformity improvements by modulating RF field and plasma distribution through forcing the plasma wave front to be perpendicular to the side edges where the ferrite blocks are positioned.

In some embodiments, the plasma processing chamber 200B may be operatively connected to a zero field feed through (ZFFT) 230B. The ZFFT 230B may minimize parasitic plasma. A parasitic plasma may be generated in the gas feed lines due to the existence of a high electrical field within the gas feed lines. The ZFFT 230B helps eliminate the parasitic plasma within the gas feed lines which reduces the particle formation upstream of the diffuser plate 203B. Furthermore, the ZFFT 230B may be operatively connected to a remote plasma source (RPS) 232B. The RPS 232B may be operatively connected to the gas feed 234B.

In one embodiment, in addition to each of the first VHF power generator 206B1 coupled to a first RF match, the second VHF power generator 206B2 coupled to a second RF match, the third VHF power generator 206B3 coupled to a third RF match, and/or the fourth VHF power generator 206B4 coupled to a fourth RF match as discussed above, a fifth VHF power generator 240B and a fifth RF match may be operatively and electrically connected to the backing plate 201B and diffuser plate 203B through a mounting on cover plate 205B. The fifth VHF power generator 240B and a fifth RF match may be mounted on the cover plate 205B at or near the center 218B and electrically connected to the backing plate 201B and diffuser plate 203B there through.

Referring to both FIG. 1 and FIG. 2B, a controller 220B is operatively connected to the chamber body 102 of the plasma processing system 100 and/or the VHF power generators 206B1, 206B2, 206B3 and 206B4. Controller 220B is substantially similar to controller 220A. Furthermore, controller 220B contains the same components as those of controller 220A, including a CPU 222B, memory 224B, and support circuits 226B, each of which is substantially similar to the CPU 222A, the memory 224A, and the support circuits 226A described respectively above. In one embodiment, the controller 220B is programmed to control operation of each of the first VHF power generator 206B1, the second VHF power generator 206B2, the third VHF power generator 206B3, and/or the fourth VHF power generator 206B4. In some embodiments, the controller 220B is programmed to control operation of each of the first VHF power generator 206B1, the second VHF power generator 206B2, the third VHF power generator 206B3, and/or the fourth VHF power generator 206B4 at a first frequency via each associated match in such a way that the four VHF power generators 206B1, 206B2, 206B3 and 206B4 with four corner feeds to each corner location of the backing plate 201B respectively, could be controlled for sinusoidal or arbitrary phase modulation and sweeping at approximately 200 μs per period to quickly sustain the plasma in process volume. The modulation or sweeping frequencies are slightly different with randomized phase relationship to each corner location of the backing plate 201B or to two sets of corner locations to generate the desired effect for improved uniformity and to smoothly minimize fluctuations in the reflected power. In some embodiments, the first frequency may be between about 20 MHz and about 100 MHz, for example, between about 30 MHz and about 70 MHz, such as about 60 MHz. In some embodiments, the controller 220B may control each of the VHF generators at slightly different frequencies and at patterned or randomized phase relationships between any individual VHF generators or two sets of VHF generators to provide improved plasma uniformity. In one embodiment, the controller 220B is programmed to control the fifth VHF power generator 240B in addition to the first VHF power generator 206B1, the second VHF power generator 206B2, the third VHF power generator 206B3, and/or the fourth VHF power generator 206B4. In some embodiments, the controller 220B may be programmed to control the fifth VHF power generator at a second frequency between about 20 MHz and about 100 MHz, for example at frequency different from the first frequency, such as about 40 MHz while the controller 220B rotates frequencies between each of the other VHF generators are at slightly different frequencies such as 60.1 MHz and 60 MHz to create a push-pull effect at the corners of the chamber.

FIG. 2C is a schematic perspective view of plasma processing chamber components 200C for a plasma enhanced chemical vapor deposition system, according to one embodiment. The plasma processing chamber components 200C include chamber lid assembly 204C and substrate support susceptor 202C. The susceptor 202C may be utilized in the plasma enhanced chemical vapor deposition system 100, as shown in FIG. 1, such as within and/or coupled to the chamber body 102 of the plasma processing system 100, in lieu of substrate support 104. It is contemplated, however, that the disclosed susceptor 202C and chamber lid assembly 204C may be utilized in and/or with any suitable plasma processing chamber. As shown, the susceptor 202C includes ground straps 242C and ground contacts 244C and is disposed opposite the chamber lid assembly 204C. In some embodiments, the chamber lid assembly 204C includes the cover plate 205C, the backing plate 201C and the diffuser plate 203C. In some embodiments, the diffuser plate 203C is electrically coupled to the backing plate 201C. In other embodiments, a skirt (not shown) may be disposed between the diffuser plate 203C and the backing plate 201C. In some embodiments, the diffuser plate 203C and backing plate 201C are coupled to a lid of the chamber body 102 of the plasma processing system 100, such as, for example, lid assembly 109 shown in FIG. 1 or cover plate 205C shown in FIG. 2C. The diffuser plate 203C and backing plate 201C may have a shape similar to a shape of the cover plate 205C and/or a shape with at least four distinct sides. It is contemplated, however, that the backing plate 201C, the diffuser plate 203C and/or the cover plate 205C may have any suitable shape and/or any suitable number of sides.

The backing plate 201C and/or the diffuser plate 203C assist with the modifying of the uniformity pattern of a thin film deposited in the plasma processing chamber which includes as least one radio frequency (RF) power source disposed therein. In some embodiments, the RF power source(s) may be a VHF power generator.

The plasma processing chamber 200C includes a plurality of VHF power generators 206C1 and 206C2. Each VHF power generator 206C1 and 206C2 are coupled to the backing plate 201C and diffuser plate 203C via cover plate 205C at a location disposed approximate an edge 262 of the cover plate 205C. In certain embodiments, and as shown in FIG. 2C, two VHF power generators 206C1 and 206C2 may be electrically coupled to the diffuser plate 203C via openings (not shown) in cover plate 205C. Each of the VHF power generators 206C1 and 206C2 may be disposed opposite each other along edges 262 and approximately centered along opposing edges. Also, each VHF power generator 206C1 and 206C2 is configured to generate power. Power may be generated at a frequency between about 20 MHz and about 100 MHz. In certain embodiments, a first VHF power generator 206C1 may generate power a first frequency, while a second VHF power generator 206C2 may generate power at a second frequency. Each of the plurality of the VHF power generators 206C1 and 206C2 may be further configured to generate power in any suitable phase difference (e.g., out of phase) with one another and/or at a frequency that is different than a frequency of power generated by any other VHF power generator, for example 180 degrees apart at the match output. By way of example only, in some embodiments, the first VHF power generator 206C1 may have VHF fed therein at a fixed match of 60 MHz. Furthermore, the second VHF power generator 206C2 may have VHF fed therein at a fixed match of at 60.1 MHz. As such, a phase of 60 MHz shifts at 0.1 MHz, relative to 60.1 MHz, thus creating a phase sweeping.

As shown in FIG. 2C, the cover plate 205C has an opening 216C at a substantial center 218C of the cover plate 205C. In some embodiments, a gas feed 234C may be disposed through the opening 216C. As such, the opening 216C is configured to hold and/or support the gas feed 234C.

Furthermore, at least one magnetic ferrite block 260 is coupled to the backing plate 201C. In certain embodiments, the at least one magnetic ferrite block 260 may be disposed in a gap between the backing plate 201C and the cover plate 205C. In one embodiment, at least two magnetic ferrite blocks 260 are positioned in the gap between the backing plate 201C and the cover plate 205C. In one embodiment the magnetic ferrite blocks 260 are positioned towards the opposing side edges 262 of the cover plate 205C and diffuser plate 203C and not at edges 262 that have the opposing VHF power generators 206C mounted on the top side of the cover plate 205C. In some embodiments the magnetic ferrite blocks 260 are positioned along edges of the backing plate 201C that have the greatest length. The magnetic ferrite blocks further assist with plasma uniformity improvements by modulating RF field and plasma distribution through forcing the plasma wave front to be perpendicular to the side edges where the ferrite blocks are positioned.

In some embodiments, the plasma processing chamber 200C may be operatively connected to a zero field feed through (ZFFT) 230C. The ZFFT 230C may minimize parasitic plasma. A parasitic plasma may be generated in the gas feed lines due to the existence of a high electrical field within the gas feed lines. The ZFFT 230C helps eliminate the parasitic plasma within the gas feed lines which reduces the particle formation upstream of the diffuser plate 203C. Furthermore, the ZFFT 230C may be operatively connected to a remote plasma source (RPS) 232C. The RPS 232C may be operatively connected to the gas feed 234C.

Referring to both FIG. 1 and FIG. 2C, a controller 220C is operatively connected to the chamber body 102 of the plasma processing system 100 and/or each of the VHF power generators 206C1 and 206C2. Controller 220C is substantially similar to controller 220A and/or controller 220B. Furthermore, controller 220C contains the same components as those of controller 220A and/or controller 220B, including a CPU 222C, memory 224C, and support circuits 226C, each of which is substantially similar to the CPU 222A, 222B the memory 224A, 224B, and the support circuits 226A, 226B described respectively above. The controller 220C is programmed to control operation of each of the first and second VHF power generators 206C1 and 206C2. In some embodiments, the controller 220C is programmed to control operation of each VHF power generator 206C1 and 206C2 at a first frequency via an automatic match or a fixed match in such a way that the VHF power generators 206C1 and 206C2, with feeds to each location on the backing plate 201C respectively, could be controlled for sinusoidal or arbitrary phase modulation and sweeping at approximately 200 μs per period to quickly sustain the plasma in process volume. The modulation or sweeping frequencies are slightly different with randomized phase relationship between each location to generate the desired effect for improved uniformity and to smoothly minimize fluctuations in the reflected power. In some embodiments, the first frequency may be between about 20 MHz and about 100 MHz, for example, between about 30 MHz and about 70 MHz, such as about 60 MHz. In one embodiment, the first VHF power generator 206C1 is configured to provide power out of phase with that provided by the second VHF power generator 206C2, for example 180 degrees apart at the match output. By way of example only, in some embodiments, the first VHF power generator 206C1 may have a VHF fed therein at 60 MHz and the second VHF power generator 206C2 may have VHF fed therein at fixed matches at 60.1 MHz and 180 degrees apart at match output. As such, a phase of 60 MHz shifts at 0.1 MHz, relative to 60.1 MHz, thus creating a phase sweeping modulation.

Benefits of each of the embodiments of the plasma processing chambers components 200A, 200B, 200C, shown in FIGS. 2A, 2B, 2C, respectively, allow for plasma uniformity improvements via phase modulation, sweeping, and/or providing rotating push and pull at the corners.

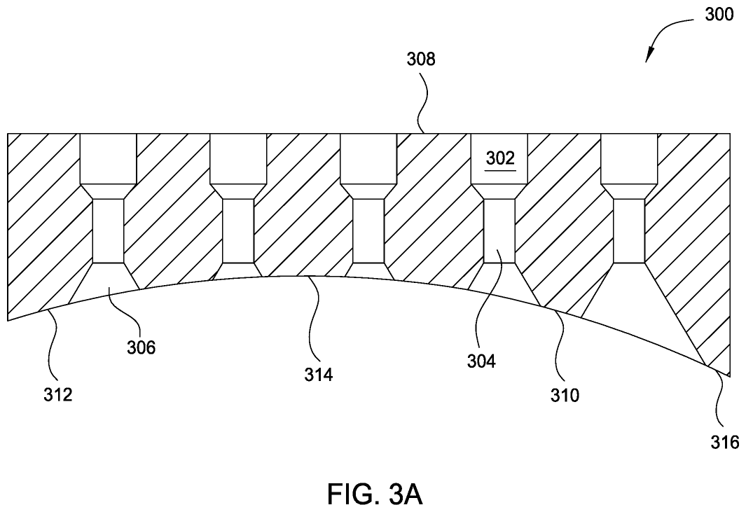

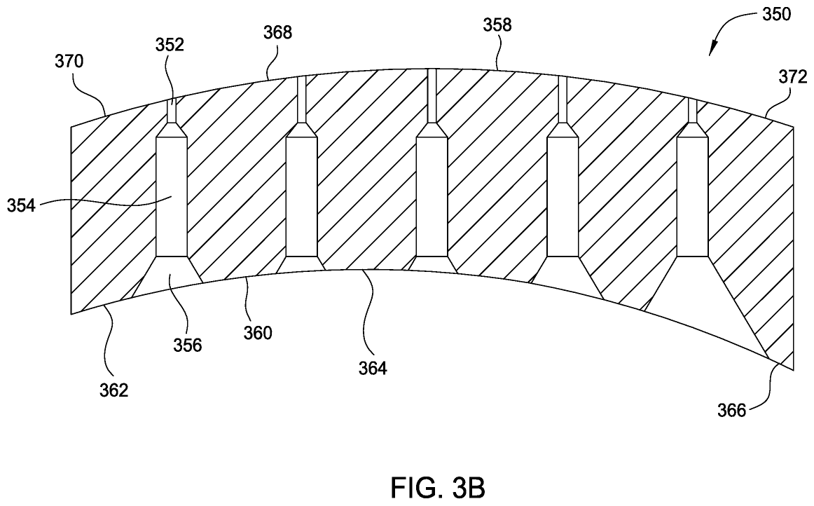

FIG. 3A is a schematic cross-sectional view of a diffuser plate 300, according to one embodiment. Diffuser plate 300 may be utilized in lieu of diffuser plate 203A, diffuser plate 203B, or diffuser plate 203C shown in FIG. 2A, FIG. 2B, or FIG. 2C, respectively. Furthermore, diffuser plate 300 may be utilized in the chamber body 102 of the plasma processing system 100, described supra. Diffuser plate 300 utilizes a dual cone design. As shown in FIG. 3A, the top bore 302 and the choke 304 for each gas passage extending between the upstream surface 308 and the downstream surface 310 are substantially identical. The hollow cathode cavities 306, however, may be different across the diffuser plate 300. The hollow cathode cavities 306 closest to the slit valve may have a smaller surface area and/or volume as compared to the hollow cathode cavities 306 corresponding to the edge of the diffuser plate 300. The hollow cathode cavities 306 corresponding to the slit valve may have a surface area and/or volume greater than the surface area and/or volume of the hollow cathode cavities 306 corresponding to the center of the diffuser plate 300. The hollow cathode cavities 306 may be different due to the undulating shape of the downstream surface 310. In some embodiments, the choke 304 length and/or width may be varied to facilitate flow pattern modulation. The downstream surface 310 may have a concave portion 314 off-center of the downstream surface 310 that gently slopes to an edge portion 316 and another portion 312 near the slit valve. The concave portion 314 may have a Gaussian shape. In some embodiments, however, the downstream surface 310 may have a concave portion 314 on-center of the downstream surface 310 that gently slopes to an edge portion 316 and another portion 312 near the slit valve. The downstream concave surface 310 may be formed by machining out the downstream surface 310 of the diffuser plate 300 after the top bore 302 and hollow cathode cavities 306 have been drilled into the diffuser plate 300.

Benefits of the dual cone design include improved uniform film deposition onto a substrate by compensating for a slit valve in the diffuser plate design. The dual cone design shown in FIG. 3A enables plasma and flow modulation thus improving plasma uniformity by compensating for the standing wave effect. Also, back pinhole scooping allows for flow pattern modulation.

FIG. 3B is a schematic cross-sectional view of a diffuser plate 350, according to one embodiment. Diffuser plate 350 may be utilized in lieu of diffuser plate 203A, diffuser plate 203B, or diffuser plate 203C shown in FIG. 2A, FIG. 2B, or FIG. 2C, respectively. Furthermore, diffuser plate 350 may be utilized in the chamber body 102 of the plasma processing system 100, described supra. Diffuser plate 350 utilizes a single cone design. As shown in FIG. 3B, the top bore 352 and the mid bore 354 for each gas passage extending between the upstream surface 358 and the downstream surface 310 are substantially identical. The hollow cathode cavities 356, however, may be different across the diffuser plate 350. The hollow cathode cavities 356 closest to the slit valve may have a smaller surface area and/or volume as compared to the hollow cathode cavities 356 corresponding to the edge of the diffuser plate 350. The hollow cathode cavities 356 corresponding to the slit valve may have a surface area and/or volume greater than the surface area and/or volume of the hollow cathode cavities 356 corresponding to the center of the diffuser plate 350. The hollow cathode cavities 356 may be different due to the undulating shape of both the downstream surface 360 and the upstream surface 358. The downstream surface 360 may have a concave portion 364 off-center of the downstream surface 360 that gently slopes to an edge portion 366 and another portion 362 near the slit valve. In some embodiments, however, the downstream surface 360 may have a concave portion 364 on-center of the downstream surface 360 that gently slopes to an edge portion 366 and another portion 362 near the slit valve. The downstream surface 360 may be formed by machining out the downstream surface 360 of the diffuser plate 350 after the top bore 352, the mid bore 354 and hollow cathode cavities 356 have been drilled into the diffuser plate 350. Furthermore, the upstream surface 358 may have a convex portion 368 off-center of the upstream surface 358 that gently slopes to an edge portion 372 and another portion 370 near the slit valve. In some embodiments, however, the upstream surface 358 may have a convex portion 368 on-center of the upstream surface 358 that gently slopes to the edge portion 372 and another portion 370 near the slit valve. The upstream surface 358 may be formed by machining the upstream surface 358 of the diffuser plate 350 after the top bore 352 and hollow cathode cavities 356 have been drilled into the diffuser plate 350.

The single cone design shown in FIG. 3B enables plasma and flow modulation thus improving plasma uniformity by compensating for the standing wave effect. Furthermore, benefits of both the diffuser plate 300 of FIG. 3A and the diffuser plate 350 of FIG. 3B include counteraction of the standing wave effect. It is further contemplated that the diffuser 103 may include dual cone designs and/or single cone designs with a front concave scoop and/or a back convex scoop to enable modulation of plasma density and/or gas flow patterns.

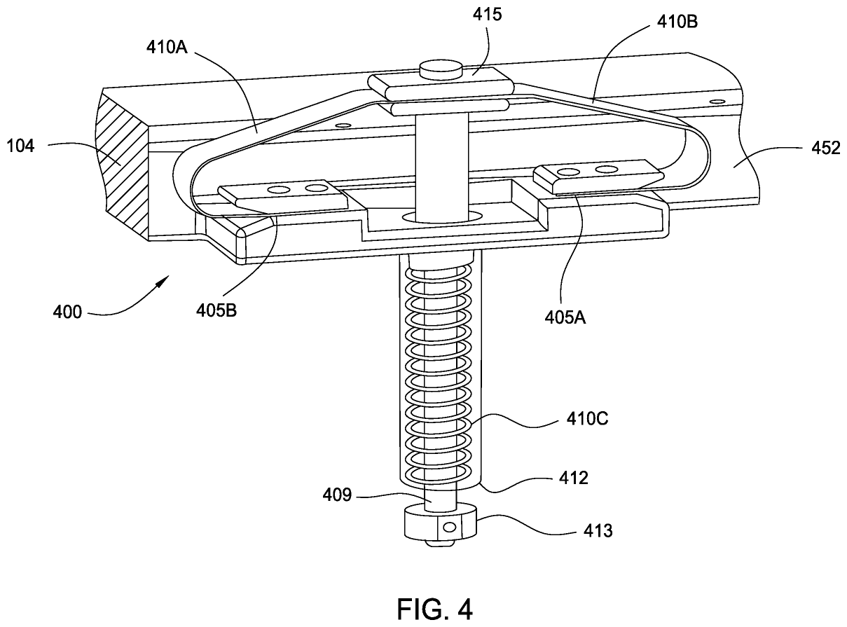

FIG. 4 is an isometric view of one embodiment of a compressible contact member 400 coupled to a bracket 452. In this embodiment, the bracket 452 is configured as a bar that is coupled to a susceptor, such as substrate support 104 referred to in FIG. 1. Spring forms 410A, 410B may be made of materials having properties that carry or conduct an electrical current. In one embodiment, the spring forms 410A, 410B may be a continuous single sheet material or a single flat spring having two ends 405A, 405B. Alternatively, the spring forms 410A, 410B may be two separate, discontinuous pieces of sheet material or two flat springs coupled at respective ends at the contact pad 415. In this embodiment, a collar 413 is shown that is coupled to a second shaft 409 disposed within the tubular member 412. The collar 413 may be made of a conductive material, such as aluminum or anodized aluminum. The collar 413 may comprise a nut or include a threaded portion for a set screw that is adapted to fix to the second shaft 409. The second shaft 409 may be of a reduced dimension, such as a diameter, to allow the spring form 410C to fit thereover.

Embodiments of the compressible contact member 400 described may allow the substrate support to be grounded to the chamber wall above the slit valve opening. Embodiments of the compressible contact members as described herein creates individual ground contact units which mount to the substrate support and or chamber sidewall. In one embodiment, as the substrate support moves up, the compressible contact members engage on fixed grounded contact pads on surfaces of the chamber above the slit valve opening. The compressible contact member units contain a compliant component which allows the substrate support to maintain a ground contact over a range of process spacing distances. When the substrate support is lowered, the grounding contact units disengage from the grounded contact pads. Embodiments of the compressible contact members as described herein allows the susceptor to be grounded to the chamber body above the slit valve opening eliminating the slit valve opening affecting the RF return path. Also, since the ground contact units are each mounted to the substrate support independently and since they have a compliant component they do not rely on surfaces being flat to achieve good electrical contacts. Additional benefits of the compressible contact member 400 include that susceptor grounding may be adjusted and/or modulated to compensate for any asymmetry of film depositions for uniformity improvement. in some embodiments, the susceptor grounding may be adjusted or modulaetd by removing grounding straps from the sides of the suscpetor that have the greatest length. In some embodiments, the susceptor grounding may be adjusted or modulated by using grounding straps with different widths and/or lengths.

To summarize, the embodiments disclosed herein relate to a plasma processing system for modifying the uniformity pattern of a thin film deposited in a plasma processing chamber which includes at least one VHF power generator coupled to a diffuser within the plasma processing chamber. The feeding location offset of each VHF power generator and the controlling of each VHF power generator via phase modulation and sweeping allows for plasma uniformity improvements by compensating for the non-uniformity of the thin film patterns produced by the chamber, due to the standing wave effect. The power distribution between the multiple VHF power generators coupled to and/or disposed at different locations on the backing plate may be produced by dynamic phase modulation between the VHF power applied at the different coupling points.

While the foregoing is directed to embodiments of the present disclosure, other and further embodiments of the disclosure may be devised without departing from the basic scope thereof, and the scope thereof is determined by the claims that follow.

What is claimed is:

1. A plasma processing chamber, comprising:
a diffuser;
a backing plate coupled to the diffuser, wherein the backing plate has a first corner location, a second corner location, a third corner location, and a fourth corner location, and wherein the backing plate has an opening at a substantial center of the backing plate for a gas feed; and
a VHF power generator coupled to the backing plate at the first corner location, the second corner location, the third corner location, and the fourth corner location.

2. The plasma processing chamber of claim 1, wherein the backing plate is coupled to a lid of the plasma processing chamber.

3. The plasma processing chamber of claim 1, further comprising a controller operatively connected to the VHF power generator, wherein the controller is programmed to control operation of the VHF power generator at a first frequency via an automatic match, and the first frequency is between about 30 MHz and about 70 MHz.

4. The plasma processing chamber of claim 3, wherein the controller is further programmed to perform phase modulation and sweeping.

5. A plasma processing chamber, comprising:
a diffuser;
a backing plate coupled to the diffuser, wherein the backing plate has an opening at a substantial center of the backing plate for a gas feed;
a first VHF power generator coupled to the backing plate at a first radius from a center of the backing plate and at a first azimuth angle;
a second VHF power generator coupled to the backing plate at a second radius from the center of the backing plate and at a second azimuth angle;
a third VHF power generator coupled to the backing plate at a third radius from the center of the backing plate and at a third azimuth angle;
a fourth VHF power generator coupled to the backing plate at a fourth radius from the center of the backing plate and at a fourth azimuth angle; and
a controller operatively connected to the plasma processing chamber, wherein the controller is programmed to control operation of the first VHF power generator, the second VHF power generator, the third VHF power generator, and the fourth VHF power generator.

6. The plasma processing chamber of claim 5, wherein the backing plate is coupled to a lid of the plasma processing chamber.

7. The plasma processing chamber of claim 5, wherein the controller is programmed to control operation of the first VHF power generator, the second VHF power generator, the third VHF power generator, and the fourth VHF power generator at a first frequency via an automatic match, and the first frequency is between about 30 MHz and about 70 MHz.

8. The plasma processing chamber of claim 5, wherein the controller is further programmed to perform phase modulation and sweeping.

9. The plasma processing chamber of claim 5, wherein the second VHF power generator and the fourth VHF power generator each generate power at a frequency between about 35 MHz and about 75 MHz; and the second VHF power generator is configured to provide power out of phase with that provided by the fourth VHF power generator.

10. The plasma processing chamber of claim 5, wherein the first VHF power generator and the third VHF power generator each generate power at a frequency different than that of the second VHF power generator and the fourth VHF power generator.

11. The plasma processing chamber of claim 5, wherein the first VHF power generator is configured to provide power out of phase with that provided by the third VHF power generator.

12. The plasma processing chamber of claim 5, further comprising at least one magnetic ferrite block coupled to the backing plate, and the magnetic ferrite block is disposed in a gap between the backing plate and a cover plate.

13. A plasma processing chamber, comprising:
a diffuser;
a backing plate coupled to the diffuser, wherein the backing plate has an opening at a substantial center of the backing plate for a gas feed;
a plurality of VHF power generators, wherein each VHF power generator is coupled to the backing plate at a location disposed approximate an edge of the backing plate; and
at least one magnetic ferrite block coupled to the backing plate.

14. The plasma processing chamber of claim 13, wherein the at least one magnetic ferrite block is disposed in a gap between the backing plate and a cover plate.

15. The plasma processing chamber of claim 13, further comprising:
a controller operatively connected to the plasma processing chamber, wherein the controller is programmed to control operation of the each VHF power generator, and the controller is further programmed to perform phase modulation and sweeping.
